(19) United States
(12) Patent Application Publication
(10) Pub. No.: US 2014/0368256 A1
(43) Pub. Date: Dec. 18, 2014

(54) SEMICONDUCTOR SYSTEMS

(71) Applicant: SK hynix Inc., Icheon-si (KR)

(72) Inventor: Kwang Soon KIM, Mokpo-si (KR)

(73) Assignee: SK hynix Inc., Icheon-si (KR)

(21) Appl. No.: 14/132,217

(22) Filed: Dec. 18, 2013

(30) Foreign Application Priority Data
Jun. 17, 2013 (KR) 10-2013-0069280

(51) Int. Cl. H03K 17/16

(52) U.S. Cl. CPC H03K 17/165
USPC 327/434

(57) ABSTRACT

Semiconductor systems are provided. The semiconductor system includes a first semiconductor device and a second semiconductor device. The first semiconductor device includes a buffer circuit that outputs a drive signal generated according to a comparison result of an input signal and an output signal through a first node, drives a second node in response to the drive signal, and divides a voltage level of the second node to generate the output signal through a third node. The second semiconductor device includes a stabilization circuit that is connected to the third node through a connector to stabilize the output signal.

### CROSS-REFERENCE TO RELATED APPLICATION

The present application claims priority under 35 U.S.C 119(a) to Korean Application No. 10-2013-0069280, filed on Jun. 17, 2013, in the Korean Intellectual Property Office, which is incorporated herein by reference in its entirety as set forth in full.

### BACKGROUND

1. Technical Field

Embodiments of the present disclosure generally relate to semiconductor systems including semiconductor devices and buffer circuits.

2. Related Art

In general, at least one semiconductor device may be mounted on a printed circuit board (PCB) acting as an important element of a semiconductor system. The semiconductor device may execute some functions such as logic operations with an appropriate drive voltage supplied from an external device. To execute the logic operations, the semiconductor device may receive input signals generated from an external device.

The input signals may be buffered by buffer circuits (also, referred to as ‘input protection circuits’) of the semiconductor device and may be transmitted to internal circuits of the semiconductor device. The buffer circuits may include static buffer circuits having a simple configuration. The static buffer circuit may be realized using an inverter that has a PMOS transistor and an NMOS transistor which are serially connected between a power voltage terminal and a ground voltage terminal. The static buffer circuit may have an advantage of a simple configuration. However, the static buffer circuit may have weak noise immunity to reduce an allowable swing range of the input signals or may malfunction in high frequency operations.

Accordingly, a buffer circuit having the same or similar configuration as a differential amplifier may be widely employed in the semiconductor devices having weak noise immunity or operating at a high frequency. The buffer circuit having the same or similar configuration as the differential amplifier may be referred to as a dynamic buffer circuit.

### SUMMARY

Various embodiments are directed to semiconductor systems.

According to various embodiments, a semiconductor system includes a first semiconductor device and a second semiconductor device. The first semiconductor device includes a buffer circuit that outputs a drive signal generated according to a comparison result of an input signal and an output signal through a first node, drives a second node in response to the drive signal, and divides a voltage level of the second node to generate the output signal through a third node. The second semiconductor device includes a stabilization circuit that is connected to the third node through a connector to stabilize the output signal.

According to further embodiments, a semiconductor system includes a controller and a first semiconductor device. The controller generates a control signal, a power voltage signal and a ground voltage signal. The first semiconductor device includes a buffer circuit that outputs a drive signal generated according to a comparison result of an input signal and an output signal through a first node, receives the drive signal to drive a second node to the power voltage signal, and divides a voltage level of the second node to generate the output signal through a third node. The buffer circuit includes a first stabilization element coupled between the first node and an internal node and a switching element coupled between the internal node and the second node. The switching element is turned on in response to the control signal.

According to further embodiments, a semiconductor system includes a first semiconductor device including a first stabilization element and suitable for buffering an input signal, generate an output signal, and stabilize a voltage level of the output signal with the first stabilization element in response to a voltage level of a control signal; and a second semiconductor device including a stabilization circuit and suitable for stabilizing the voltage level of the output signal instead of the first stabilization element in response to the voltage level of the control signal, wherein the first semiconductor device is located apart from the second semiconductor device and electrically coupled to one another through a connector.

### BRIEF DESCRIPTION OF THE DRAWINGS

Embodiments of the present invention will become more apparent in view of the attached drawings and accompanying detailed description, in which:

FIG. 1 is a block diagram illustrating a semiconductor system according to various embodiments of the present invention;

FIG. 2 is a circuit diagram illustrating a buffer circuit included in the semiconductor system of FIG. 1;

FIG. 3 is a circuit diagram illustrating a stabilization circuit included in the semiconductor system of FIG. 1; and

FIG. 4 is a circuit diagram illustrating a buffer circuit, a stabilization circuit and a connector included in the semiconductor system of FIG. 1.

### DETAILED DESCRIPTION

Embodiments of the present invention will be described hereinafter with reference to the accompanying drawings. However, the embodiments described herein are for illustrative purposes only and are not intended to limit the scope of the invention.

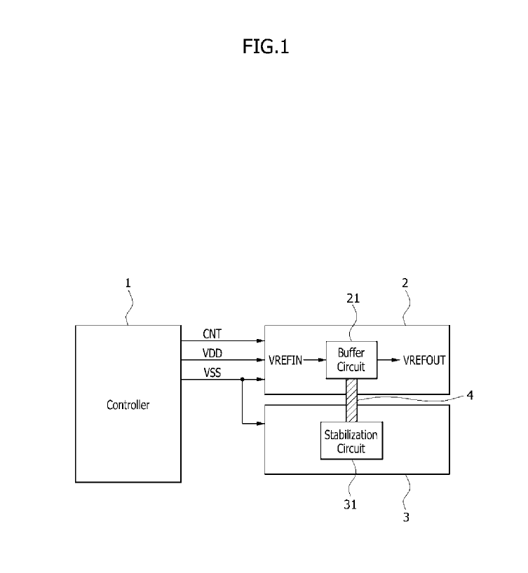

Referring to FIG. 1, a semiconductor system according to various embodiments of the present invention may include a controller 1, a first semiconductor device 2, a second semiconductor device 3 and a connector 4. The controller 1 may apply a control signal CNT, a power voltage signal VDD and a ground voltage signal VSS to the first and second semiconductor devices 2 and 3. The first semiconductor device 2 may include a buffer circuit 21 that buffers an input signal VREFIN in response to the control signal CNT, the power voltage VDD and the ground voltage VSS to generate an output signal VREFOUT. The second semiconductor device 3 may include a stabilization circuit 31 having a first terminal connected to the ground voltage signal VSS terminal and a second terminal connected to the buffer circuit 21 through the connector 4. The control signal CNT may be disabled to have a logic “low” level (i.e., low voltage level) when the connector 4 electrically connects the stabilization circuit 31 to the buffer circuit 21 and may be enabled to have a logic “high” level (i.e., high voltage level) when the connector 4 electrically disconnects the stabilization circuit 31 to the buffer circuit 21. The connector 4 may be realized using a conductive via, for example, a through silicon via (TSV) that physically penetrates the first and second semiconductor devices 2 and 3. The buffer circuit 21 may buffer one of various input signals according to the embodiments to generate an output signal. According to the present embodiments, each of the input signals VREFIN and the output signals VREFOUT may be a reference voltage signals.

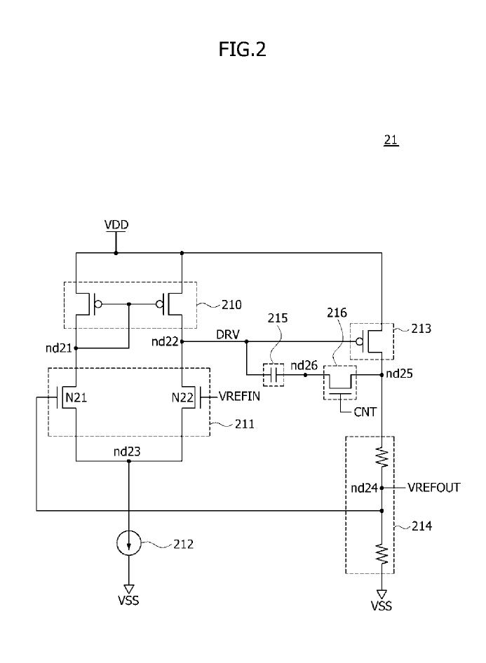

Referring to FIG. 2, the buffer circuit 21 may include a constant current supplier 210, a signal input unit 211, a current source 212, a driving unit 213, a voltage divider 214, a first stabilization element 215 and a switching element 216. The constant current supplier 210 may be realized using a current mirror circuit connected to a power voltage VDD terminal to supply a constant current to nodes ND21 and ND22. The signal input unit 211 may include an NMOS transistor N21 turned on in response to the output signal VREFOUT and an NMOS transistor N22 turned on in response to the input signal VREFIN. The NMOS transistor N21 may be coupled between the node ND21 and a node ND23, and the NMOS transistor N22 may be coupled between the node ND22 and the node ND23. When the input signal VREFIN has a higher level than the output signal VREFOUT, the NMOS transistor N22 may be turned on stronger than the NMOS transistor N21 to pull down a drive signal DRV on the node ND22. Thus, the drive signal DRV may be driven to have a logic “low” level. In contrast, when the input signal VREFIN has a lower level than the output signal VREFOUT, the NMOS transistor N22 may be turned on weaker than the NMOS transistor N21 to pull up the drive signal DRV on the node ND22. Thus, the drive signal DRV may be driven to have a logic “high” level. The current source 212 may be coupled between the node ND23 and a ground voltage VSS terminal. The current source 212 may act as a constant current source that outputs a constant current through the node ND23. The driving unit 213 may be coupled between the power voltage VDD terminal and a node ND25. The driving unit 213 may drive the node ND25 to have the power voltage VDD when the drive signal DRV has a logic “low” level and may terminate a drive of the node ND25 when the drive signal DRV has a logic “high” level. The voltage divider 214 may divide a voltage level of the node ND25 to output the output signal VREFOUT through a node ND24. As shown in FIG. 2, the voltage divider 214 may also be electrically coupled with the ground voltage VSS terminal. The first stabilization element 215 may be realized using a capacitor which is coupled between the node ND22 and a node ND26. The switching element 216 may be coupled between the node ND26 and the node ND25 and may be turned on in response to the control signal CNT. The first stabilization element 215 may prevent a voltage between the nodes ND22 and ND25 from abruptly changing when the switching element 216 is turned on. Thus, a level of the output signal VREFOUT generated by diving the voltage level of the node ND25 may also be stabilized because of the presence of the first stabilization element 215 even though the switching element 216 is turned on. Although not shown in FIG. 2, the node ND24 though which the output signal VREFOUT is outputted may be electrically connected to the stabilization circuit 31 via the connector 4.

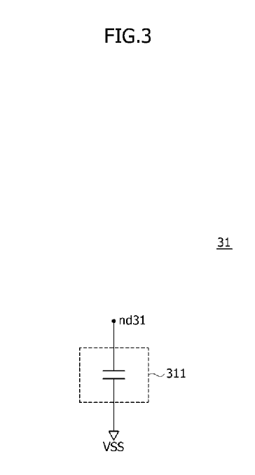

Referring to FIG. 3, the stabilization circuit 31 may include a second stabilization element 311 which is coupled between a node ND31 and the ground voltage VSS terminal. The node ND31 may be connected to the buffer circuit 21 through the connector 4. The second stabilization element 311 may be realized using a capacitor and may stably maintain a voltage difference between the node ND31 and the ground voltage VSS terminal. When the node ND31 is connected to the node ND24 through which the output signal VREFOUT is outputted, the output signal VREFOUT may have a stable level without any discontinuity regardless of noise. This is due to the presence of the second stabilization element 311. That is, a level of the output signal VREFOUT may be stabilized. In some embodiments, a capacitance value of the second stabilization element 311 may be greater than that of the first stabilization element 215. The second stabilization element 311 may be directly connected to the ground voltage VSS terminal. Thus, it may prevent a power supply rejection ratio (PSRR) characteristic relating to noise of the power voltage VDD from being degraded.

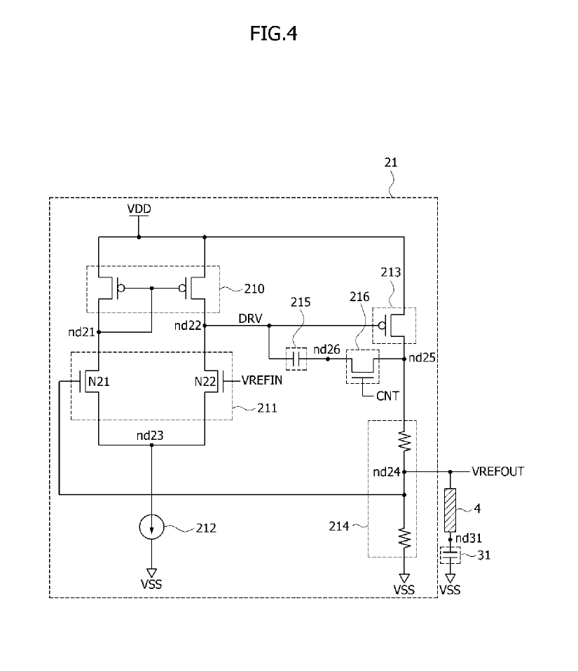

Referring to FIG. 4, the buffer circuit 21 and the stabilization circuit 31 may be connected to each other through the connector 4. Furthermore, the connector 4 may be electrically coupled with node nd24, the output signal VREFOUT being outputted from node nd24. The buffer circuit 21 included in the first semiconductor device (2 of FIG. 1) may buffer the input signal VREFIN to generate the output signal VREFOUT. The buffer circuit 21 may include the first stabilization element 215, as described above. Thus, the buffer circuit 21 may stably maintain a level of the output signal VREFOUT when the switching element 216 is turned on in response to the control signal CNT having a logic “high” level. However, in the event that the buffer circuit 21 and the stabilization circuit 31 are electrically connected to each other through the connector 4, the control signal CNT may be disabled to turn off the switching element 216. In such a case, the output signal VREFOUT may be stabilized by the stabilization circuit 31 instead of the first stabilization element 215. The detailed configuration of the buffer circuit 21 has been already described with reference to FIG. 2. Thus, the detailed configuration of the buffer circuit 21 will be omitted hereafter. The stabilization circuit 31 may be included in the second semiconductor device (3 of FIG. 1). The stabilization circuit 31 may be coupled between a node ND31 and the ground voltage VSS terminal, and the node ND31 may be connected to the buffer circuit 21 through the connector 4.

As described above, the semiconductor system according to the embodiments may be configured such that an output terminal of the first semiconductor device 2 is electrically connected to the stabilization circuit 31 of the second semiconductor device 3 to stabilize the output signal VREFOUT of the buffer circuit 21 included in the first semiconductor device 2. The stabilization circuit 31 may be realized by a capacitive element having a greater capacitance value than the first stabilization element 215. Thus, an area that the stabilization circuit 31 occupies may be greater than an area that the first stabilization element 215 occupies. However, the semiconductor system according to the embodiments may stabilize a level of the output signal VREFOUT of the buffer circuit 21 included in the first semiconductor device 2 using the stabilization circuit 31 of the second semiconductor device 3. Thus, an area that the buffer circuit 21 occupies may be reduced. That is, the level of the output signal VREFOUT of the buffer circuit 21 can be stabilized using the stabilization circuit 31 of the second semiconductor device 3 separated from the first semiconductor device 2. Accordingly, an area of the first semiconductor device 2 may be reduced.

What is claimed is:

1. A semiconductor system comprising:
a first semiconductor device suitable for including a buffer circuit that outputs a drive signal generated according to a comparison result of an input signal and an output signal through a first node, drives a second node in response to the drive signal, and divides a voltage level of the second node to generate the output signal through a third node; and
a second semiconductor device suitable for including a stabilization circuit that is connected to the third node through a connector to stabilize the output signal.

2. The semiconductor system of claim 1, wherein the stabilization circuit includes a stabilization element which is coupled between a fourth node connected to the connector and an external voltage terminal to stably maintain a voltage difference between the fourth node and the external voltage terminal.

3. The semiconductor system of claim 2, wherein the external voltage terminal is a ground voltage terminal which is directly connected to the stabilization element.

4. The semiconductor system of claim 2, wherein the connector is a conductive via penetrating the first and second semiconductor devices.

5. The semiconductor system of claim 2, wherein the stabilization element includes a capacitor.

6. The semiconductor system of claim 5, wherein the first stabilization element includes a capacitor which has a capacitance value that is less than a capacitance value of the capacitor of the stabilization element.

7. The semiconductor system of claim 1, wherein the buffer circuit includes:
a stabilization element coupled between the first node and an internal node; and
a switching element coupled between the internal node and the second node,
wherein the switching element is turned on in response to a control signal.

8. The semiconductor system of claim 7, wherein the control signal is enabled to turn on the switching element when the connector electrically disconnects the buffer circuit to the stabilization circuit.

9. The semiconductor system of claim 7, wherein the buffer circuit further includes:
a voltage divider suitable for dividing a voltage level of the second node to generate the output signal; and
a signal input unit suitable for receiving the input signal and the output signal to drive the drive signal.

10. A semiconductor system comprising:
a controller suitable for generating a control signal, a power voltage signal and a ground voltage signal; and
a first semiconductor device suitable for including a buffer circuit that outputs a drive signal generated according to a comparison result of an input signal and an output signal through a first node, receives the drive signal to drive a second node to the power voltage signal, and divides a voltage level of the second node to generate the output signal through a third node,
wherein the buffer circuit comprises:
a first stabilization element coupled between the first node and an internal node; and
a switching element coupled between the internal node and the second node and turned on in response to the control signal.

11. The semiconductor system of claim 10, further comprising a second semiconductor device suitable for including a stabilization circuit that is connected to the third node through a connector to stabilize the output signal.

12. The semiconductor system of claim 11, wherein the control signal is enabled to turn on the switching element when the connector electrically disconnects the buffer circuit to the stabilization circuit.

13. The semiconductor system of claim 11, wherein the stabilization circuit includes a second stabilization element which is coupled between a fourth node connected to the connector and a ground voltage terminal receiving the ground voltage signal to stably maintain a voltage difference between the fourth node and the ground voltage terminal.

14. The semiconductor system of claim 13, wherein the connector is a conductive via penetrating the first and second semiconductor devices.

15. The semiconductor system of claim 13, wherein the second stabilization element include a capacitor having a capacitance value which is greater than that of the first stabilization element.

16. The semiconductor system of claim 10, wherein the buffer circuit further includes:
a voltage divider suitable for dividing a voltage level of the second node to generate the output signal; and
a signal input unit suitable for receiving the input signal and the output signal to drive the drive signal.

17. A semiconductor system comprising:
a first semiconductor device including a first stabilization element and suitable for buffering an input signal, generate an output signal, and stabilize a voltage level of the output signal with the first stabilization element in response to a voltage level of a control signal; and
a second semiconductor device including a stabilization circuit and suitable for stabilizing the voltage level of the output signal instead of the first stabilization element in response to the voltage level of the control signal,
wherein the first semiconductor device is located apart from the second semiconductor device and electrically coupled to one another through a connector.

18. The semiconductor system of claim 17, wherein the stabilization circuit includes a capacitance element having a greater capacitance value than a capacitance value of a capacitance element of the first stabilization element.

19. The semiconductor system of claim 17, wherein an area of the first stabilization element is less than an area of the stabilization circuit.
